(19) United States
(12) Patent Application Publication
(10) Pub. No.: US 2003/0177634 A1
(43) Pub. Date: Sep. 25, 2003

(54) Subtractive process for fabricating cylindrical printed circuit boards

(76) Inventor: Terrel L. Morris, Garland, TX (US)

Correspondence Address: HEWLETT-PACKARD DEVELOPMENT COMPANY, Intellectual Property Administration, P.O. Box 272400, Fort Collins, CO, 80527-2400, US

(21) Appl. No.: 10/383,321

(22) Filed: Mar. 6, 2003

Related U.S. Application Data
(63) Continuation-in-part of application No. 09/489,381, filed on Jan. 21, 2000.

(51) Int. Cl. H05K 3/00; H05K 3/36

(52) U.S. Cl. 29/829; 29/830; 29/831; 29/846

(57) ABSTRACT

A subtractive process for the fabrication of cylindrical printed circuit boards is presented. Layers of metal and dielectric are sequentially placed on the outside of a cylindrical form. The form may be rotated about its longitudinal axis during many of the process steps allowing automatic application of dielectric and metal layers and also allows controllable curing and etching processes.

### CROSS-REFERENCE TO RELATED APPLICATIONS

The present application is a continuation-in-part application of Ser. No. 09/489,381 (filed Jan. 21, 2000). application Ser. No. 09/489,381 is hereby incorporated herein by reference.

### FIELD OF THE INVENTION

This invention relates generally to the field of electronic printed circuit boards and more particularly to cylindrical printed circuit boards.

### BACKGROUND OF THE INVENTION

Planar printed circuit boards are well known in the art. However, some applications, such as construction of high-performance connectors, have density and performance requirements that currently are not well met by commercially available connectors. Many current connectors negatively impact signal propagation due to their introduction of discontinuities in conductor spacing, conductor width, and dielectric coefficient. These discontinuities result from the connector being manufactured from materials differing from those used in the printed circuit boards. Signals propagating through such a connector will be degraded by reflections caused by these discontinuities. The simultaneous requirements for robust connectivity, serviceability, and excellent electrical properties have resulted in a series of design trade-offs that delivered less than optimal signal performance, particularly in the 90-degree configurations often used to connect a backplane to a daughter card.

Many computer systems are built with a backplane/daughter board configuration. In this type of construction, the backplane may severely limit the speed of the computer. Signals travelling from one daughter board through the backplane to another daughter board are degraded by the two connectors, and the backplane itself adds delay. This delay through the backplane is dependent on the distance between the two daughter boards. The daughter board spacing is determined by the maximum height of components attached to any daughter board. Since the backplane must be built to accommodate any combination of daughter boards, the maximum possible height of components determines the minimum connector spacing on the backplane. If a cylindrical backplane were fabricated, the daughter boards would radiate out from the center cylindrical backplane. The tallest components would be attached to the outer parts of the daughter board and only very short components would be attached near the connector of the daughter board. This would allow the daughter board spacing along the surface of the cylindrical backplane to be determined by the size of the connector and not by the maximum component height. Since the distance between connectors is shortened, the delay due to the backplane is likewise shortened.

Industries such as communications or the oil industry need the capability of sending electronics down drill holes, through pipes or through other hollow cylindrical shapes for the purpose of surveying, inspecting, cleaning, or testing the pipes, holes or conduits. Using a cylindrical circuit board, it may be easier to construct the necessary circuits for any of the tasks required within a pipe or other cylindrical opening.

There is a need in the art for a manufacturing process capable of producing a circuit board with a cylindrical shape. The completed circuit board may be used as a connector, backplane, or cylindrical circuit. Manufacturability will be maximized if the process easily lends itself to automation, and if the process uses commonly available materials, technology, and process steps.

### SUMMARY OF THE INVENTION

A cylindrical circuit board is fabricated in a manner allowing use as a connector, computer backplane, or simply as a cylindrical circuit board. A unique manufacturing process allows a wide variety of designs while simultaneously allowing volume production.

Similar to a planar printed circuit board, the cylindrical circuit board may contain a large quantity of interconnecting traces, thru-holes or solder pads for placement of discrete components, and virtually any other structure possible with a planar circuit board. The cylindrical circuit board may be built around any size cylindrical core to produce cylindrical circuit boards of any diameter and length. Photolithographic processes may be used in the fabrication of these boards similar to the processes used in planar circuit board fabrication.

Many aspects of this process may be varied while still using the basic design and manufacturing process steps described. Thus the finished circuit board may be easily adapted to the specific requirements of many different applications.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1A through FIG. 1L consist of twelve process step descriptions showing one method for constructing the cylindrical printed circuit board and its use as a 90-degree connector.

FIG. 2 is a drawing of the cross-section of the finished connector assembly connecting a backplane to a daughter card.

FIG. 3 is a drawing showing one of the possible pad array patterns that can be plated on the flat side of the connector assembly.

FIG. 4A and FIG. 4B are drawings showing how pads may be selectively connected to ground layers or signal traces as required.

FIG. 5A and FIG. 5B are drawings showing how connection patterns for single-ended and differential signals may be optimized.

FIG. 6 is a drawing of a differential signal array as viewed looking into a flat side of the finished connector.

FIG. 7A through FIG. 7D are drawings showing four of the more efficient types of stripline layers that may be constructed with the cylindrical printed circuit board process.

FIG. 8A and FIG. 8B are drawings of two different types of embedded-wire constructions.

FIG. 9 is a detailed view of the cut line.

FIG. 10 is a side view of a cylindrical power/ground plane layer with cutouts in place.

### DETAILED DESCRIPTION

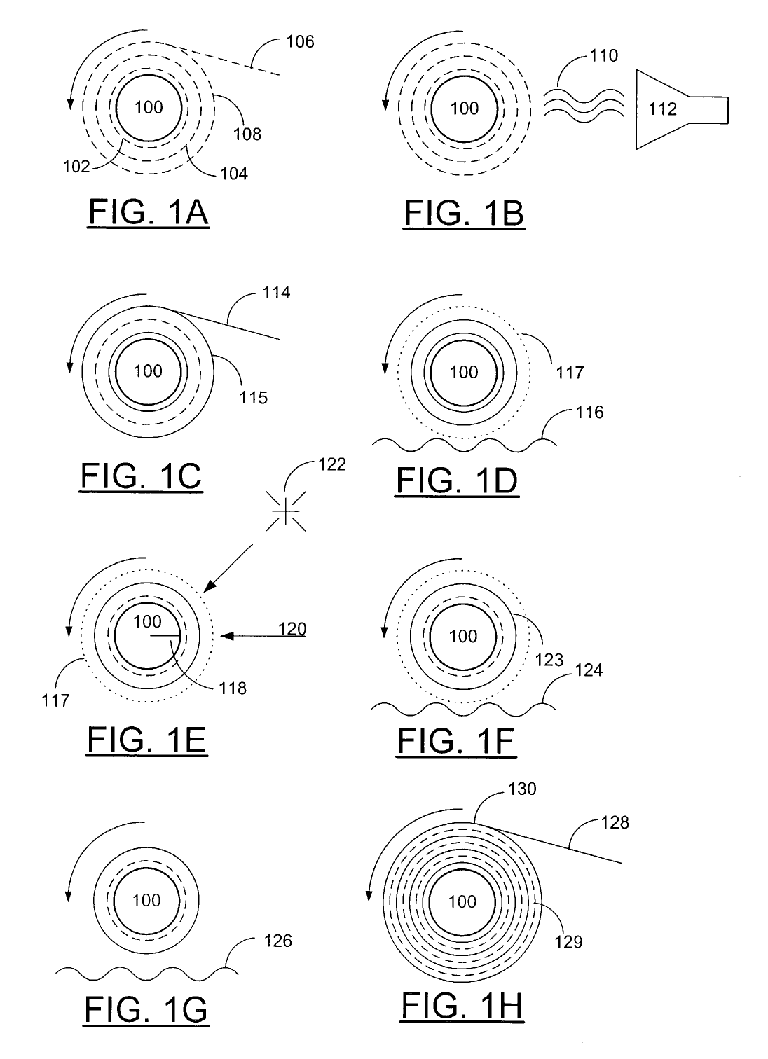

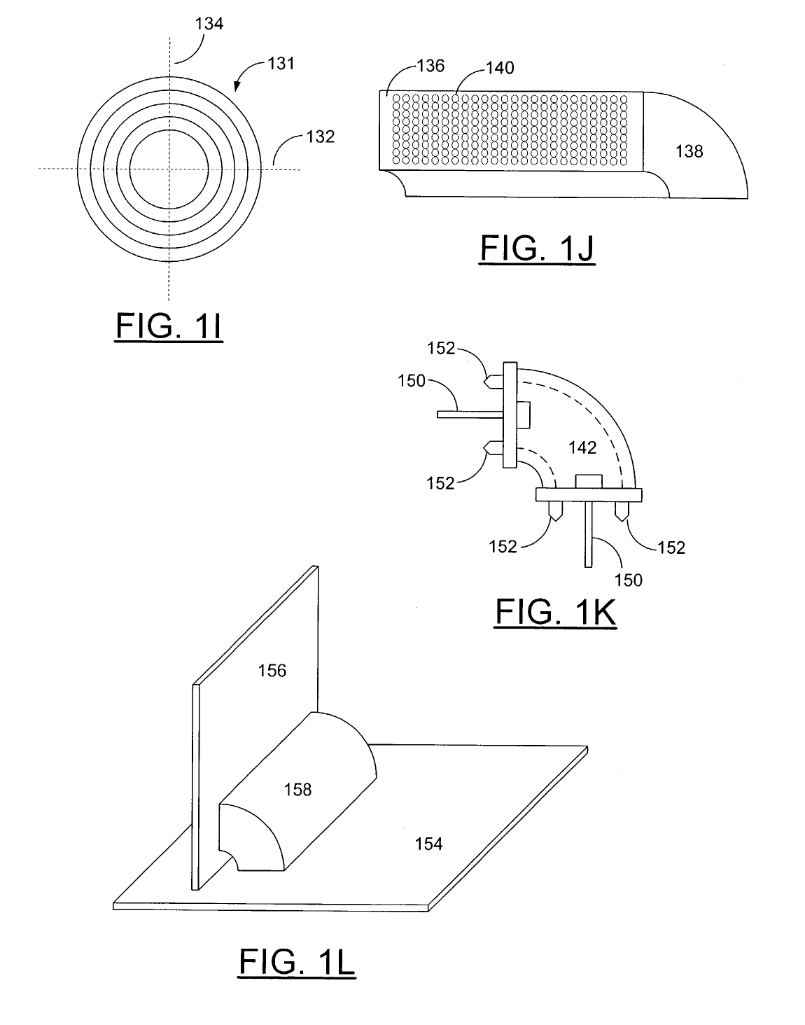

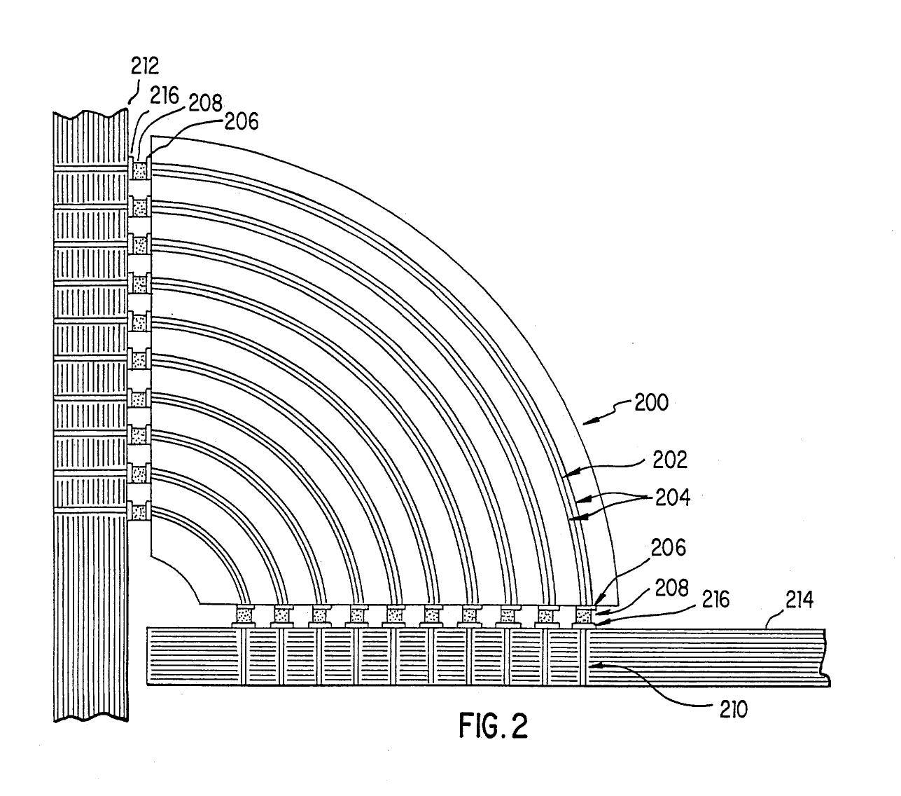

FIG. 1A through FIG. 1L consist of twelve process step descriptions showing one method for constructing the cylindrical printed circuit board and its use as a 90-degree connector. In brief, a cylinder is formed, comprising concentric layers of connecting metal, separated by concentric layers of dielectric material. A series of process steps are followed, many of them taking advantage of the fact that the cylinder may be rotated during each process step. The rotation of the cylinder about the lengthwise axis eases application of materials, curing steps, imaging, roll forming, and steps requiring immersion or partial immersion in liquids. Note that FIGS. 1A through 1L do not show each dielectric and metal layer for each step. Since there may be a large number of successive layers applied, only the outermost layers are shown for clarity.

In FIG. 1A dielectric layers 102, 104, 108 are wound around the outside of a cylindrical form 100 made of metal, glass, ceramic, plastic, or any other material deemed suitable for this application. In FIGS. 1A through 1H dielectric layers are shown as long dashed lines. The dielectric 106 may be wound in individual strands, as is common in the manufacture of fishing rods and fiberglass radio antennae. It may be rolled on in sheets or layers, or it may be sprayed in place. If it is rolled on in sheets or layers, the seams may be aligned by indexing them to occur in a specific position on the cylinder. The dielectric material 106 may be epoxy/glass, Teflon, mylar, or ceramic, or others as required by the desired application. If required, an opposing roller may be used to control thickness of the dielectric to precise dimensions.

In FIG. 1B the dielectric layers are cured as required. Ultraviolet light, infrared heat lamps, ovens or other curing processes may be applied as needed to meet the requirements of the materials. In the example embodiment of the present invention shown in FIG. 1B an infrared heat lamp 112 emits infrared light 110 that is used to cure the dielectric layers 102, 104, 108.

In FIG. 1C copper (or other metal) foil 114 is applied to form a metal layer 115. In FIGS. 1A through 1H metal layers are shown as solid lines. This metal may be coated with adhesive and rolled in place, may be plated in place, sputtered in place, or otherwise deposited on the outside of the cylinder. Alternatively, an additive process may be used. For example, the signal traces may be made of round, flat, or oval wire, wound in place around the cylinder to form stripline conductors. This wire may be plain, or may be coated with dielectric materials and/or adhesive materials.

In FIG. 1D photo-resist material 116 is added to the outside of the metal layer forming a photo-resist layer 117 to provide a means of controlled pattern etching if a subtractive process is to be used. In FIGS. 1A through 1H photo-resist layers are shown as short dashed lines. If the metal application process to be used is an additive process, i.e. the signal traces and ground layers are selectively applied, then this step is not needed.

In FIG. 1E the photo-resist layer 117 is imaged as required to provide proper signal trace width and location, or proper power/ground pattern images. If the metal application process to be used is an additive process, then this step is not needed. In this example embodiment of the present invention the photo-resist layer 117 is selectively exposed to light from a light source 122. Since this step may require alignment with previous etched layers, a reference mark 118 on the cylindrical form 100 is detected by a position sensor 120 allowing precision rotation of the cylinder.

FIG. 1F shows the etching of the metal layer 115 in a liquid metal etch 124 as required to form the single metal layer 115 into a plurality of conductors 123. If the metal application process to be used is an additive process, then this step is not needed. Alternatively, if metal were deposited, plated, rolled, formed, or otherwise applied in uniform fashion to the cylinder, a mechanical cutting process or laser imaging process could be used to form individual conductors as required.

In FIG. 1G the photo-resist, if used, is stripped from the cylinder in a liquid photoresist strip 126 and the surface prepared for an additional dielectric layer 129. If alternative metal processes or wire processes were used in the creation of signal traces, then the appropriate surface preparation process step is used in place of photo-resist.

FIG. 1H shows the addition of an additional dielectric layer 129, an additional metal layer 130, and an additional photo-resist layer 128, in the same process as shown in FIG. 1A through FIG. 1G, or with appropriate process variations as required to maintain proper thickness, adhesion, or other desired properties.

In FIG. 1I the cylindrical form 100 may be removed and the completed cylindrical printed circuit board 131 may be sawn, cut, laser cut, or otherwise separated into quadrants. In the example embodiment of the present invention shown in FIG. 1I, a vertical cut line 134 and a horizontal cut line 132 are shown dividing the cylindrical printed circuit board into four quadrants. If required, the flat surfaces formed by the cutting operation may be sanded, buffed, polished or otherwise prepared for the addition of surface pads.

The surface pads 140 are shown in FIG. 1J on the face 136 of one quadrant of a cylindrical printed circuit board. These pads may be imaged and plated, as in standard PCB processes, or alternatively sputtered, formed, or welded in place. Pads may then be plated with the desired surface finish, including, but not limited to gold, palladium/nickel, tin/lead, or tin/antimony. In place of separate pads, the interposer connection array may be directly welded, plated, or otherwise conductively attached to the signal traces and ground planes exposed on the flat surface of the conductor.

FIG. 1K shows the end plates or other hardware that is added in an example embodiment of the present invention to permit accurate location of the connector assembly to the PCB, and to permit retention of the connector and daughter card to the backplane. In this example embodiment of the present invention, pins 150 are used to physically connect the connector 142 to other planar printed circuit boards. Other alignment pins 152 are used to align the connector 142 to the planar boards. Note that the connector 142 may alternatively be bolted to the daughter card, and held in place to the backplane by card cage mechanical features such as levers, cams, thumbscrews or other devices. The connector may also be constructed such that it has ball grid array (BGA) solder balls, solder columns, or solder paste applied to the pads at the daughter card interface, and it may be reflow soldered for a semi-permanent attachment to the daughter card.

FIG. 1L illustrates that the connector length, number of layers, and other physical form factors may be adjusted as needed by each potential application, or a series of standard shapes and sizes may be developed. In the example embodiment of the present invention shown in FIG. 1L, one quadrant 158 of a cylindrical printed circuit board has surface pads 140 on the two faces of the connector. These surface pads electrically connect a motherboard 154 to a daughter board 156 in this example use of the present invention.

FIG. 2 is a drawing of the cross-section of the finished connector assembly 200 connecting a backplane to a daughter card. In this embodiment of the invention, the laminated connector board has been constructed in a printed circuit board type of process around a cylindrical core. This printed circuit board cylinder was then sectioned along the lengthwise axis into quadrants forming four 90-degree laminated connector boards. An example of the type of process used to build this cylindrical printed circuit board is shown in FIG. 1A through FIG. 1L and described above. The connector assembly 200 connects a backplane 212 to a daughter card 214. The connector assembly 200 features plated pads 206, that use an array of elastomeric, stamped, or fuzz-button interposer contacts, or solder balls 208 to connect to PCB pads 216 and vias 210. The plated pads 206 are formed on the edges of the board where the cylinder was cut into quarters. Signal conductors 202 are surrounded by ground planes 204, using spacing and dielectric materials common to PCBs. The signal conductors 202 and ground planes 204 are designed such that only one signal reaches the cut lines of the cylinder so that when the plated pads 206 are formed there are no electrical shorts between adjacent traces. Thus each signal layer may be completely shielded from each adjacent layer. The length of the connectors may be set by the desired number of signal/power/ground traces that need to be connected between the backplane 212 and a daughter card 214. Since signals propagate in the same conductor materials as the PCB, and are surrounded by the same dielectrics as used in a PCB, they travel at the same velocity, and in the same mode of propagation as signals within the PCB.

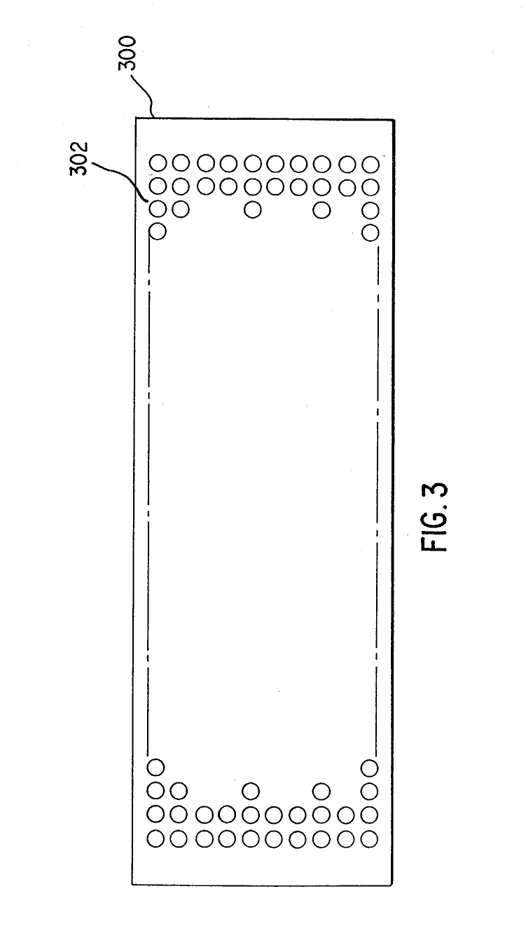

FIG. 3 is a drawing showing one of the possible pad array patterns that can be plated on the flat side of the connector assembly 300. Note that the pad shape, distance between pads on vertical or horizontal axes, pad material, and plated coatings may be varied as required by the system application. Also, the number of pads may be varied as required.

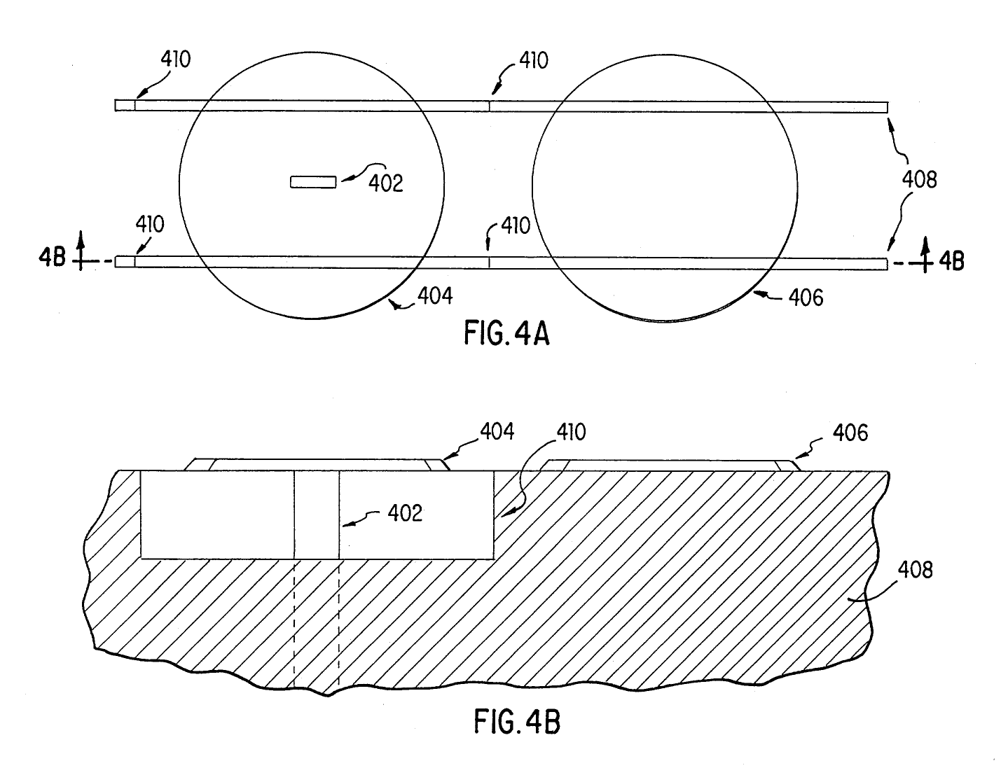

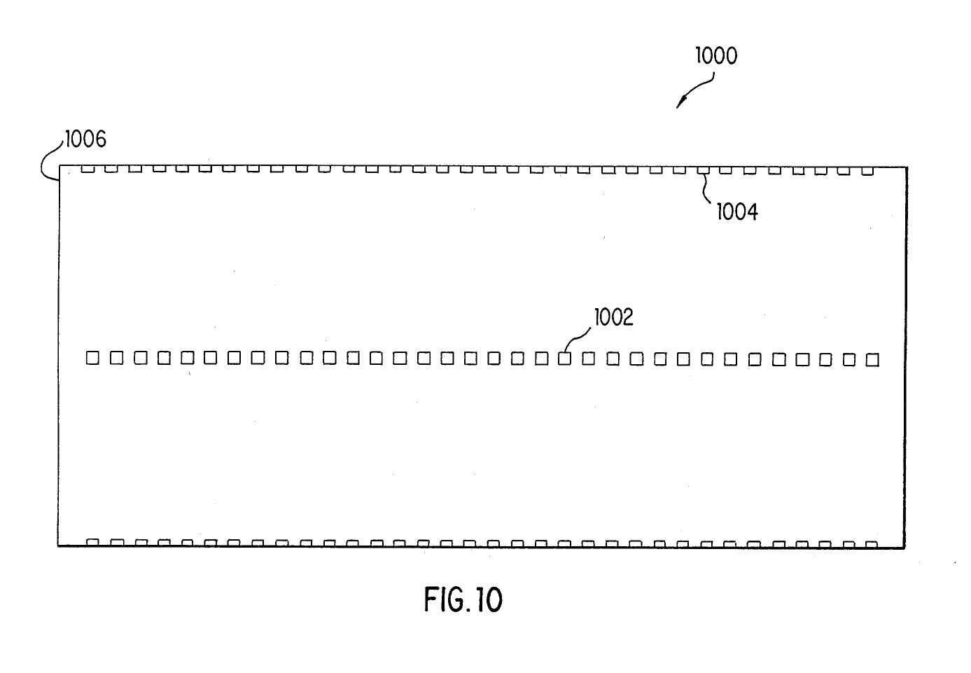

FIG. 4A and FIG. 4B are drawings showing how pads may be selectively connected to ground layers or signal traces as required. FIG. 4A is a top view showing how signal trace 402 is connected to pad 404, but isolated from ground layers 408. In FIG. 4A, pad 406 is connected to ground layers 408, providing a low-impedance ground connection to the PCB. In the cross section, FIG. 4B, the connection between signal trace 402 and pad 404 is shown, as well as the isolation from ground layers 410. Note the cut 410 in the ground layer 408 around the signal pad 404. FIG. 10, described in detail below, is a representation of one possible ground plane design. The plurality of cut outs, 1002 and 1004, in the ground plane may be seen in FIG. 1O. This keeps the ground layer 408 from shorting to the signal trace 402 through the signal pad 404. The connection between pad 406 and ground layers 408 is also shown. It may be desirable to limit the ground plane layers to protrude to the surface only in areas directly under the pads, so that no ground plane materials are exposed in areas not covered by pads. Alternatively, one ground plane layer of the pair may be assigned to power, creating a power-signal-ground stackup. The example shown uses 4 mil wide signal lines and 24 mil diameter pads on a 40 mil pitch, however many combinations of signal and pad geometries are possible using the techniques described in this document.

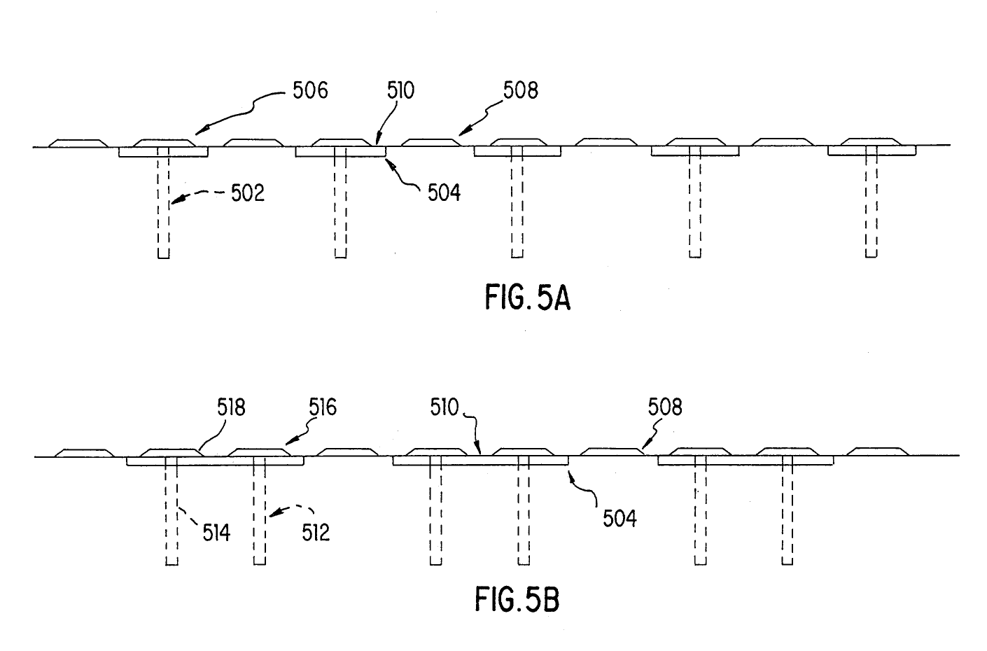

FIG. 5A and FIG. 5B are drawings showing how connection patterns for single-ended and differential signals may be optimized. Selective connections between pads and signals or pads and power/ground layers may be used to create structures that are ideal for certain types of signal propagation. Signal trace 502 is connected to pad 506, that is plated onto the flat surface of the connector body 510, but not connected to power/ground layers 504. Pad 508 is connected to power/ground layers 504, but not to the signal trace 502. In this pattern, signal pads 506 alternate with ground pads 508. Utilization of the pattern shown allows a 1:1 signal to ground ratio at the pad array and in the PCB vias, optimizing single-ended performance.

Likewise, FIG. 5B shows a differential pattern that has been optimized for true-complement pairs of signals. In this case, the pair of signal traces 512 and 514 are connected to pads 516 and 518, that are plated onto the flat surface of the connector body 510, but not connected to power/ground layers 504. Pad 508 is connected to power/ground layers 504, but not to the signal traces 512 and 514. In this pattern, groups of two signal pads 516 and 518 alternate with ground pads 508. Since two adjacent pads are used for signal traces, true-complement coupling is optimized within a signal pair, but the ground connections between pairs prevent excessive pair-to-pair coupling.

Using the basic techniques shown in FIG. 5A and FIG. 5B, many combinations of pad, signal, power, and ground combinations may be utilized to ensure optimal interconnect performance for many different signaling applications.

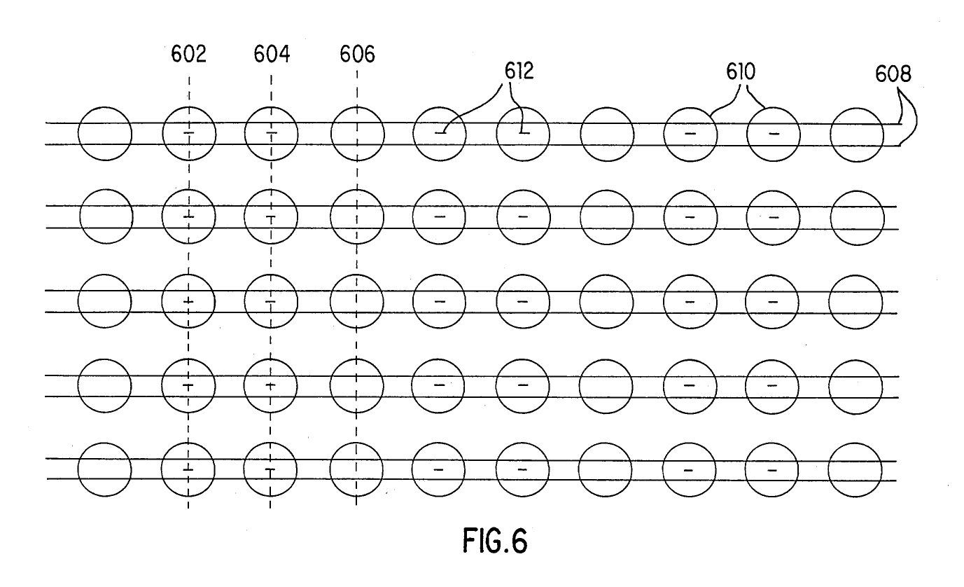

FIG. 6 is a drawing of a differential signal array as viewed looking into a flat side of the finished connector. An array of signals 612 sandwiched between power/ground planes 608 are connected to an array of circular pads 610. Signal column 602 is comprised of “true” signals, signal column 604 is comprised of “complement” signals, and the true-complement pairs are surrounded by power/ground columns 606. Note that this configuration is only one of many possible signal configurations. Staggered, inter-digitated, and offset patterns are also possible. Pad shape may also be oval, “dogbone”, square, or any other shape as dictated by connectivity optimization, capacitance minimization, and design rules.

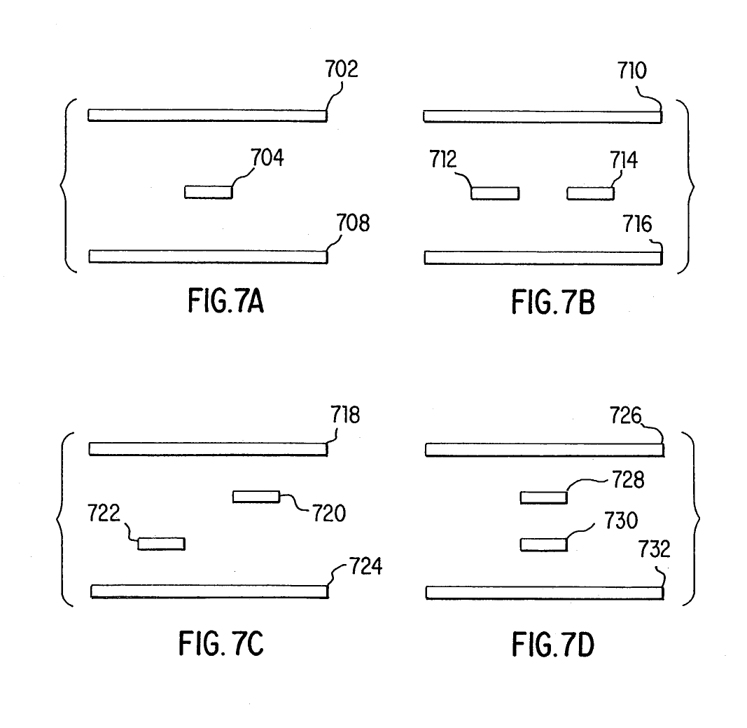

FIG. 7A through FIG. 7D are drawings showing four of the more efficient types of stripline layers that may be constructed with the cylindrical printed circuit board process. Generally, any structure that may be created in a planar PCB may be created in the cylindrical PCB process for use in a connector.

The stripline shown in FIG. 7A is a single conductor 704 sandwiched between two power/ground planes 702 and 708.

FIG. 7B shows a dual conductor stripline such as for a differential signal, with the two signal traces 712 and 714 sandwiched between two power/ground planes 710 and 716.

FIG. 7C also shows a dual conductor stripline such as for a differential signal, where the two signal traces 720 and 722 are horizontally offset and also on different conducting layers sandwiched between two power/ground planes 718 and 724.

FIG. 7D also shows a dual conductor stripline such as for a differential signal, where the two signal traces 728 and 738 are on different conducting layers sandwiched between two power/ground planes 726 and 732.

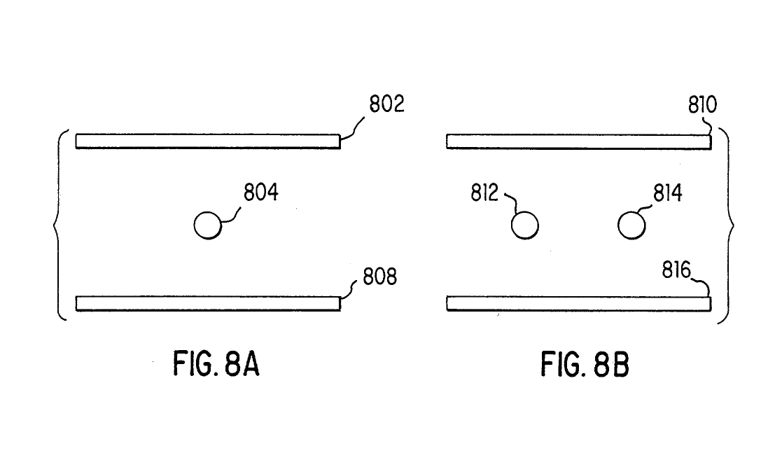

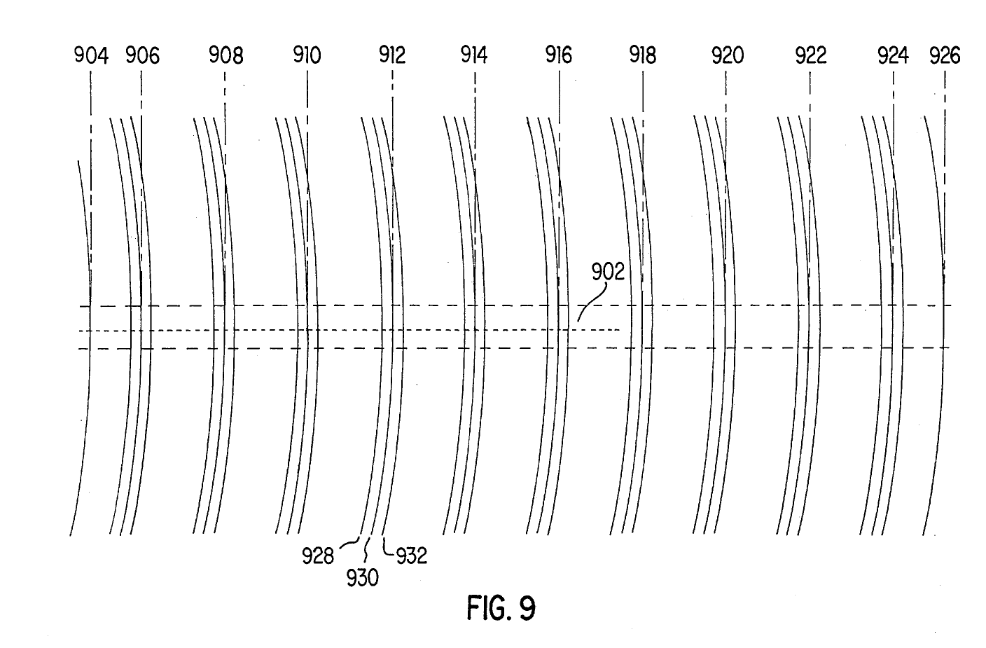

FIG. 8A and FIG. 8B are drawings of two different types of embedded-wire constructions. Other constructions using embedded wires are also possible.

FIG. 8A shows a single conductor 804 sandwiched between two power/ground planes 802 and 808. FIG. 8B shows a dual conductor such as for a differential signal with two signal wires 812 and 814 sandwiched between two power/ground planes 810 and 816.

FIG. 9 shows a detailed view of the cut line 902 axially through a cylindrical printed circuit board, and the layers formed by the various process steps. Dimensions are given for the case with signals on a 40-mil (1.016 millimeters) grid. Other spacings are possible. In the 40-mil (1.016 millimeters) grid example, point 904 is the edge at 0.0 millimeters. Point 906 is at 0.635 millimeters. Point 908 is at 1.651 millimeters. Point 910 is at 2.667 millimeters. Point 912 is at 3.683 millimeters. Point 914 is at 4.699 millimeters. Point 916 is at 5.715 millimeters. Point 918 is at 6.731 millimeters. Point 920 is at 7.747 millimeters. Point 922 is at 8.763 millimeters. Point 924 is at 9.779 millimeters. The other edge 926 is at 10.414 millimeters. Each of the signal traces 930 is sandwiched between two power/ground planes 928 and 932.

FIG. 10 shows a side view 1000 of a cylindrical power/ground plane 1006 with square cutouts 1002 and 1004 in place. The cutouts 1002 and 1004 enable selective attachments to power/ground as shown in FIG. 4. Each cutout 1002 and 1004 represents a location where a signal trace will connect to a pad.

Another embodiment of this invention may build a cylindrical printed circuit board from the inside out, rather than rolling on a center core form. In this case, the form would be a hollow cylinder that would rotate about the center axis. Sprayed, rolled, or slurried materials could be precisely deposited in this fashion. Stepper motor control, combined with accurate spray or other deposition methods may be employed to precisely deposit dielectrics and conductors as required to build the shapes needed.

Another embodiment of this invention is a process for constructing the embedded wire striplines shown in FIG. 8 that involves winding a continuous spiral of wire about a rotating cylindrical core. The pads may be offset a small amount to make up for the positional variations induced by the spiral. When the cylinder is cut for use as a connector, the wire ends are available for forming pads by a plating process. If the cylindrical printed circuit board is designed for uses other than as a connector, the spiral of wire may be cut as needed to form stripline conductors within the circuit board. Once again, stepper motor control may be used to precisely rotate the cylindrical printed circuit board under a cutting head for accurate cutting of the spiral of wire. This stripline process may be combined with planar conductor processes to form ground and power planes surrounding the stripline conductors.

The foregoing description of the present invention has been presented for purposes of illustration and description. It is not intended to be exhaustive or to limit the invention to the precise form disclosed, and other modifications and variations may be possible in light of the above teachings. The embodiments were chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A process for fabricating circuit boards comprising:
applying a dielectric layer over a substantially cylindrical rigid form, wherein said dielectric layer forms a substantially cylindrical shape surrounding said cylindrical form, and wherein said form is of sufficient rigidity to withstand the wrapping of dielectric and metal layers around the form while maintaining a substantially cylindrical shape;
curing said dielectric layer;
applying a metal layer over said dielectric layer, wherein said metal layer forms a cylinder surrounding said cylindrical form;
forming conductors from said metal layer.

2. The process for fabricating circuit boards as recited in claim 1 wherein the step of forming conductors from said first metal layer comprises:
applying a photo-resist layer over said metal layer, wherein said photo-resist layer forms a substantially cylindrical shape surrounding said cylindrical form;
imaging said photo-resist layer;
etching said metal layer;
stripping said photo-resist layer.

3. The process for fabricating circuit boards as recited in claim 2 further comprising:
applying an additional dielectric layer, wherein said additional dielectric layer forms a substantially cylindrical shape surrounding said cylindrical form; curing said additional dielectric layer;
applying an additional metal layer over said additional dielectric layer, wherein said additional metal layer forms a substantially cylindrical shape surrounding said cylindrical form;
applying an additional photo-resist layer over said additional metal layer, wherein said additional photo-resist layer forms a substantially cylindrical shape surrounding said cylindrical form;
imaging said additional photo-resist layer;
etching said additional metal layer;
stripping said additional photo-resist layer.

4. The process for fabricating circuit boards as recited in claim 3 wherein at least one of said metal layers consist of metal foil.
